(19) United States
(12) Patent Application Publication
(10) Pub. No.: US 2005/0275018 A1
(43) Pub. Date: Dec. 15, 2005

(54) Semiconductor device with multiple semiconductor layers

(76) Inventors: Suresh Venkatesan, Austin, TX (US); Mark C. Foisy, Austin, TX (US); Michael A. Mendicino, Austin, TX (US); Marius K. Orlowski, Austin, TX (US)

Correspondence Address: FREESCALE SEMICONDUCTOR, INC.;LAW DEPARTMENT, 7700 WEST PARMER LANE MD:TX32/PL02, AUSTIN, TX, 78729, US

(21) Appl. No.: 10/865,351

(22) Filed: Jun. 10, 2004

(51) Int. Cl. H01L 21/8234

(52) U.S. Cl. 257/347

(57) ABSTRACT

A semiconductor device structure uses two semiconductor layers to separately optimize N and P channel transistor carrier mobility. The conduction characteristic for determining this is a combination of material type of the semiconductor, crystal plane, orientation, and strain. Hole mobility is improved in P channel transistors when the conduction characteristic is characterized by the semiconductor material being silicon germanium, the strain being compressive, the crystal plane being (100), and the orientation being <100>. In the alternative, the crystal plane can be (111) and the orientation in such case is unimportant. The preferred substrate for N-type conduction is different from the preferred (or optimum) substrate for P-type conduction. The N channel transistors preferably have tensile strain, silicon semiconductor material, and a (100) plane. With the separate semiconductor layers, both the N and P channel transistors can be optimized for carrier mobility.

### FIELD OF THE INVENTION

This invention relates in general to semiconductor processing and in particular to a semiconductor device with multiple semiconductor layers.

### DESCRIPTION OF THE RELATED ART

Semiconductor devices are typically formed in a semiconductor layer. For example, semiconductor-on-insulator (SOI) technologies form devices within a semiconductor layer which overlies an insulator layer (such as a buried silicon dioxide) which overlies a semiconductor substrate. SOI devices allow for improved performance over traditional bulk technologies. Today, many SOI technologies integrate different types of semiconductor devices having different conductivity types (such as P-type Metal-Oxide-Semiconductor (PMOS) and N-type Metal-Oxide-Semiconductor (NMOS) field effect transistors (FETs), also referred to as PMOS and NMOS devices, respectively) into a same semiconductor layer, with the use of shallow trench isolation (STI) to electrically separate the devices from each other. Also, different types of semiconductor devices (such as PMOS and NMOS devices) can be optimized by varying various characteristics of the semiconductor layer in which they are formed. However, the starting semiconductor layer for PMOS devices and NMOS devices typically require different optimizations.

For example, the mobility and therefore the performance of PMOS and NMOS devices depend upon the crystal orientation of the semiconductor layer in which they are formed, where the best crystal orientation for PMOS devices is different from the best crystal orientation for NMOS devices. For example, PMOS mobility is highest along the (111) crystal plane surface, whereas NMOS mobility is highest along the (100) crystal plane surface. Therefore, in current technologies, devices are formed in the (100) crystal plane surface and the MOSFET channels are oriented so that current flow is along the <110> crystal directions within that plane, thus compromising performance of PMOS devices in favor of NMOS devices. Therefore, a need exists for an improved method of integrating PMOS and NMOS devices which allows for independent optimization of PMOS and NMOS devices.

### BRIEF DESCRIPTION OF THE DRAWINGS

The present invention is illustrated by way of example and not limited by the accompanying figures, in which like references indicate similar elements, and in which:

FIG. 1 illustrates a cross-sectional view of semiconductor device having multiple semiconductor layers, in accordance with one embodiment of the present invention;

FIG. 2 illustrates a cross-sectional view of the semiconductor device of FIG. 1 after formation of isolation trench openings, in accordance with one embodiment of the present invention;

FIG. 3 illustrates a cross-sectional view of the semiconductor device of FIG. 2 after formation of isolation regions, in accordance with one embodiment of the present invention;

FIG. 4 illustrates a cross-sectional view of the semiconductor device of FIG. 3, after the patterning and removal of a portion of the one of the semiconductor layers, in accordance with one embodiment of the present invention;

FIG. 5 illustrates a cross-sectional view of the semiconductor device of FIG. 4, after formation of various devices within the multiple semiconductor layers, in accordance with one embodiment of the present invention;

FIG. 6 illustrates a cross-sectional view of the semiconductor device of FIG. 5, after formation of contacts to the various devices, in accordance with one embodiment of the present invention; and

FIGS. 7-9 illustrate a cross-sectional view of a semiconductor device in accordance with an alternate embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

One embodiment of the present invention allows for the independent optimization of different types of devices, such as, for example, PMOS and NMOS devices, while maintaining the enhanced performance offered by SOI technology. One embodiment uses multiple semiconductor layers such that PMOS devices and NMOS devices can each be formed in different semiconductor layers. In this manner, one type of device can be formed in one semiconductor layer and have a different conduction characteristic from another type of device formed in a different semiconductor layer, where these different conduction characteristics can therefore be optimized differently. In one embodiment, the conduction characteristics are defined by a combination of material composition, crystal plane, orientation with respect to the MOSFET channel, and strain. (Note that in one embodiment, conduction characteristics may also be referred to as electronic transport characteristics.) In one embodiment, each semiconductor layer is independently rotated around the vector normal to its plane so that the MOSFET channels are easily aligned for optimal conduction in the direction of current flow. Also, note that in one embodiment, the semiconductor layers in which the devices are formed are the active layers of an SOI structure, thus allowing both PMOS and NMOS devices to maintain the benefits of SOI isolation.

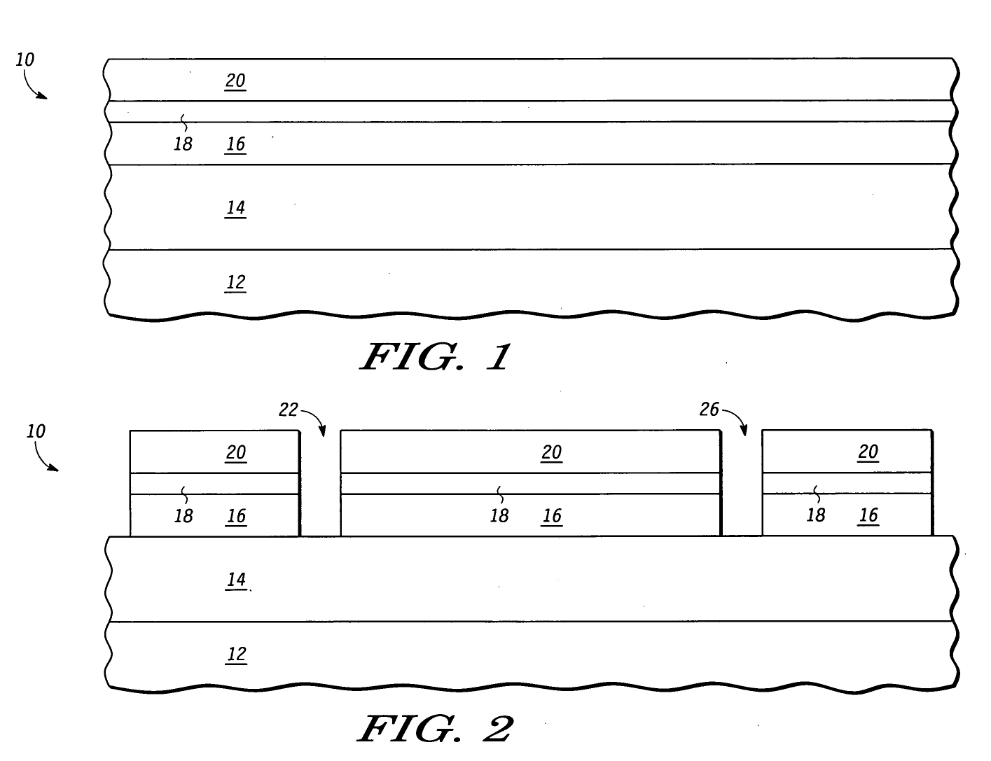

FIG. 1 illustrates a cross-sectional view of a semiconductor device 10 in accordance with one embodiment of the present invention. Semiconductor device 10 includes a substrate 12, a buried insulating layer 14 overlying substrate 12, a first semiconductor layer 16 overlying buried insulating layer 14, a bonding layer 18 overlying first semiconductor layer 16, and a second semiconductor layer 20 overlying bonding layer 18. In one embodiment, first semiconductor layer 16 will be used to form primarily one type of device, having, for example, one conductivity type, while second semiconductor layer 20 will be used to form primarily another type of device, having, for example, a different conductivity type. Therefore, in one embodiment, substrate 12 is not used to form any devices. In this embodiment, substrate 12 may be any type of material meeting the mechanical requirements for forming and supporting a semiconductor die. For example, substrate 12 may be a quartz or plastic substrate. Alternatively, substrate 12 may be any type of semiconductor substrate, such as, for example, a silicon substrate. In this case, substrate 12 may also be used to form devices.

In one embodiment, each of first semiconductor layer 16 and second semiconductor layer 20 has a thickness of less than approximately 100 nanometers (nm). The material composition and other characteristics of first semiconductor layer 16 and second semiconductor layer 20 depend upon the type of devices that will be subsequently formed using these layers and the processes used to form these devices. In one embodiment, semiconductor layer 16 may be formed of a semiconductor material, such as, for example, silicon, silicon germanium, germanium, or any combination thereof. In one embodiment, semiconductor layer 16 may be a silicon carbon alloy (Si(1−x)Cx) or a silicon carbide (SiC). In one embodiment, semiconductor layer 20 may be formed of a semiconductor material, such as, for example, silicon, silicon germanium, germanium, or any combination thereof. In one embodiment, semiconductor layer 20 may be a silicon carbon alloy (Si(1−x)Cx) or a silicon carbide (SiC).

For example, in one embodiment, first semiconductor layer 16 will be used to form PMOS devices (also referred to as P channel devices or transistors, and whose conductivity type is P-type) while second semiconductor layer 20 will be used to form NMOS devices (also referred to as N channel devices or transistors, and whose conductivity type is N-type). In this embodiment, first semiconductor layer 16 may be formed of compressively strained silicon germanium or silicon (unstrained or compressively strained) having a (100) crystal plane surface. In this embodiment, the PMOS devices may be formed in any orientation on the crystal plane surface, such as, for example, in the <110> or <100> orientation. Alternatively, first semiconductor layer 16 may be formed of unstrained or compressively strained silicon having a (111) crystal plane surface, where the PMOS devices may be formed in any channel orientation on the crystal plane surface. Or alternatively, first semiconductor layer 16 may be formed of unstrained or strained silicon having a (110) crystal plane surface, where the PMOS devices may be formed with a <−110> channel orientation. Second semiconductor layer 20 may be formed of tensile strained silicon having a (100) crystal plane surface, where the NMOS devices may be formed in any orientation on the crystal plane surface. (Note that, in alternate embodiments, first semiconductor layer 16 may be used to form NMOS devices while second semiconductor layer 20 may be used to form PMOS devices, where the respective material compositions and plane surfaces described above for each of the NMOS and PMOS devices may be used.)

In alternate embodiments, any other type of materials may be used, depending on the types of devices to be formed, where the characteristics (e.g. material composition, strain, etc.) of semiconductor layer 16 may differ from those of semiconductor layer 20. Also, the characteristics of semiconductor layers 16 and 20 may be altered throughout processing. For example, in one embodiment, each of semiconductor layers 16 and 20 may be formed of a semiconductor material, such as, for example, silicon, silicon germanium, or germanium that may be subsequently strained (either tensile or compressively strained) in later processing. In an alternate embodiment, strained silicon or silicon germanium may be used to form layers 16 and 20, in which subsequent processing modifies this strain.

In one embodiment, buried insulating layer 14 is formed of silicon dioxide. However, alternate embodiments may use different insulating materials for buried insulating layer 14. Also, in one embodiment, buried insulating layer 14 has a thickness in a range of approximately 50 nm to 200 nm. Alternatively, other thicknesses may be used. In one embodiment, bonding layer 18 has a thickness of less than 80 nm and may be used as an insulating and/or adhesive layer. For example, in one embodiment, bonding layer 18 is formed of silicon dioxide. Alternatively, other insulators may be used. In one embodiment, bonding layer 18 helps adhere second semiconductor layer 20 to first semiconductor layer 16. In alternate embodiments, different insulating and/or adhesive materials may be used for bonding layer 18, or, in yet another embodiment, a combination of bonding layers may be used. Alternatively, bonding layer 18 may not be present.

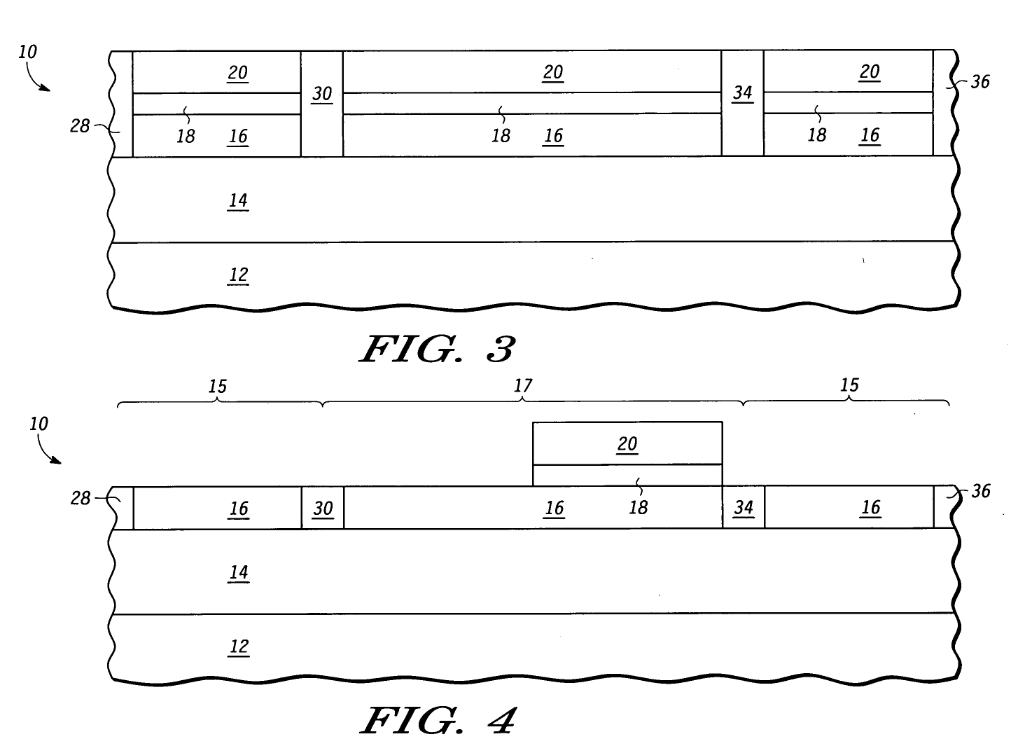

FIG. 2 illustrates a cross-sectional view of the semiconductor device 10 of FIG. 1 after formation of isolation trench openings such as openings 22 and 26. In one embodiment, the openings, such as openings 22 and 26, are formed using conventional patterning and etching techniques, and are formed such that they extend to buried insulating layer 14. Alternatively, isolation trench openings may be formed in second semiconductor layer 20 where the openings (not shown) would extend only to bonding layer 18. FIG. 3 illustrates a cross-sectional view of the semiconductor device 10 of FIG. 2 after filling of the isolation trench openings to form shallow trench isolations (STIs) 28, 30, 34, and 36 (also referred to as isolation regions 28, 30, 34, and 36, respectively). Conventional processing may be used to fill the trench openings and planarize the resulting STIs. In one embodiment, an oxide is used as the trench fill material.

FIG. 4 illustrates a cross-sectional view of the semiconductor device 10 after patterning and removing portions of second semiconductor layer 20 and bonding layer 18 to expose portions of first semiconductor layer 16. Therefore, the remaining portions of second semiconductor layer 20 (such as in a region 17) may be used to form one type of device, while the exposed portions of first semiconductor layer 16 (such as in a region 15) may be used to form another type of device. In the illustrated embodiment, note that region 17 also includes an exposed portion of first semiconductor layer 16, where this exposed portion of first semiconductor layer 16 within region 17 may be used to provide contact to a backgate for a device formed within second semiconductor layer 20 within region 17. Alternatively, region 17 may not include exposed portions of first semiconductor layer 16.

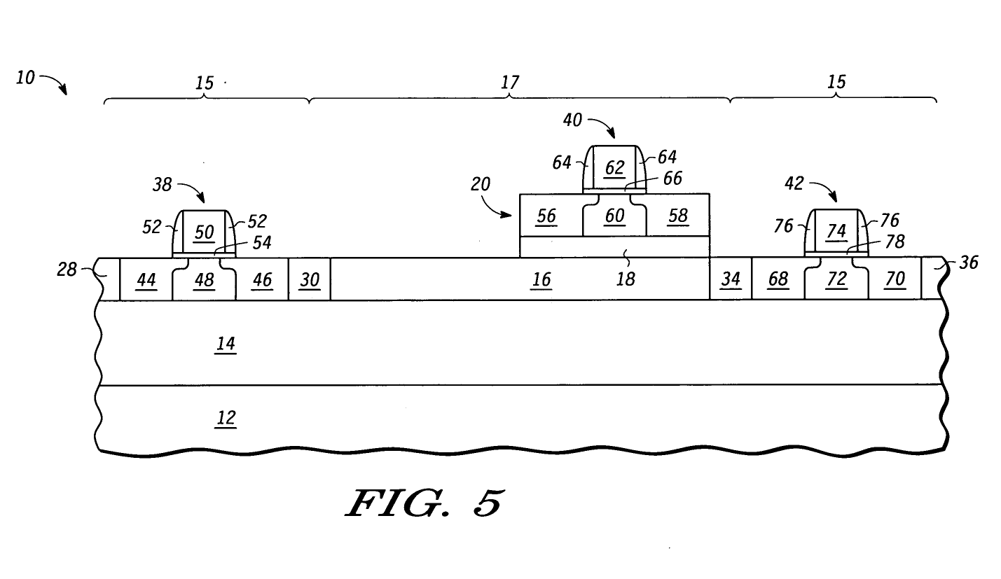

FIG. 5 illustrates a cross-sectional view of the semiconductor device 10 of FIG. 4 after formation of transistors 38, 40, and 42 (also referred to as devices 38, 40, and 42, respectively). As illustrated in FIG. 5, transistors 38 and 42 are formed in region 15, using first semiconductor layer 16, while transistor 40 is formed in region 17, using second semiconductor layer 20. Therefore, transistors 38 and 42 and transistor 40 are capable of having different conduction characteristics, due, for example, to the different characteristics of first semiconductor layer 16 and second semiconductor layer 20. These characteristics may, for example, include a combination of material composition, crystal plane and orientation, and strain. The conduction characteristics may, in turn, be determined by the characteristics of the semiconductor layer in the channel region of the transistors.

Still referring to FIG. 5, transistor 38 includes a channel region 48 and source/drain regions 44 and 46 formed within first semiconductor layer 16, where channel region 48 is located between source/drain regions 44 and 46. Transistor 38 also includes a gate dielectric 54 overlying channel region 48 and portions of source/drain regions 44 and 46, a gate 50 overlying gate dielectric 54, and sidewall spacers 52 overlying gate dielectric 54 and adjacent sidewalls of gate 50. Conventional processing and materials may be used to form transistor 38. Transistor 40 includes a channel region 60 and source/drain regions 56 and 58 formed within second semiconductor layer 20, where channel region 60 is located between source/drain regions 56 and 58. Transistor 40 also includes a gate dielectric 66 overlying channel region 60 and portions of source/drain regions 56 and 58, a gate 62 overlying gate dielectric 66, and sidewall spacers 64 overlying gate dielectric 66 and adjacent sidewalls of gate 62. Conventional processing and materials may be used to form transistor 40. Transistor 42 includes a channel region 72 and source/drain regions 68 and 70 formed within first semiconductor layer 16, where channel region 72 is located between source/drain regions 68 and 70. Transistor 42 also includes a gate dielectric 78 overlying channel region 72 and portions of source/drain regions 68 and 70, a gate 74 overlying gate dielectric 78, and sidewall spacers 76 overlying gate dielectric 78 and adjacent sidewalls of gate 74. Conventional processing and materials may be used to form transistor 42. In one embodiment, each of transistors 38, 40, and 42 are formed simultaneously. For example, each of the gate dielectrics is formed at the same time, each of the gates at the same time, etc.

In one embodiment (as discussed above), transistors 38 and 42 are PMOS transistors and transistor 40 is an NMOS transistor. Therefore, in this embodiment, the material compositions and crystal planes described above may be used for first semiconductor layer 16 and second semiconductor layer 20, where first semiconductor layer 16 is used in the formation of PMOS devices and second semiconductor layer is used in the formation of NMOS devices. Therefore, note that due to the differences in first and second semiconductor layers, transistors 38 and 42 may have different conduction characteristics as compared to transistor 40. For example, the strain and material composition of channel regions 48 and 72 may differ from that of channel region 60. In this manner, the conduction characteristics of transistors 38 and 42 may be better for the carrier mobility of PMOS transistors as compared to the conduction characteristics of transistor 40, while the conduction characteristics of transistor 40 may be better for the carrier mobility of NMOS transistors as compared to the conduction characteristics of transistors 38 and 42. Alternatively, note that transistors 38 and 42 may be NMOS transistors and transistor 40 may be a PMOS transistor, with first and second semiconductor layers 16 and 20 formed accordingly.

Note also that in one embodiment, each of regions 15 and 17 include primarily devices of the same type, however, in alternate embodiments, some devices within each of regions 15 and 17 may be of a different type, where performance of these devices is compromised in favor of the majority of the devices in the respective region. For example, in the example above where transistors 38 and 42 correspond to PMOS transistors and transistor 40 corresponds to an NMOS transistor, semiconductor device 10 may still include one or more PMOS transistors within region 17, formed within second semiconductor layer 20, and may also include one or more NMOS transistors within region 15, formed within first semiconductor layer 16.

In one embodiment, gates 50, 62, and 74 are polycrystalline silicon (i.e. polysilicon) gates which may be formed over the step introduced by the raised portion of second semiconductor layer 20. For example, gate 62 can extend out of the page (along a z axis, assuming the cross-section of FIG. 5 lies in the X-Y plane), where this region along the z axis may also be a part of region 15, which is lower than region 17.

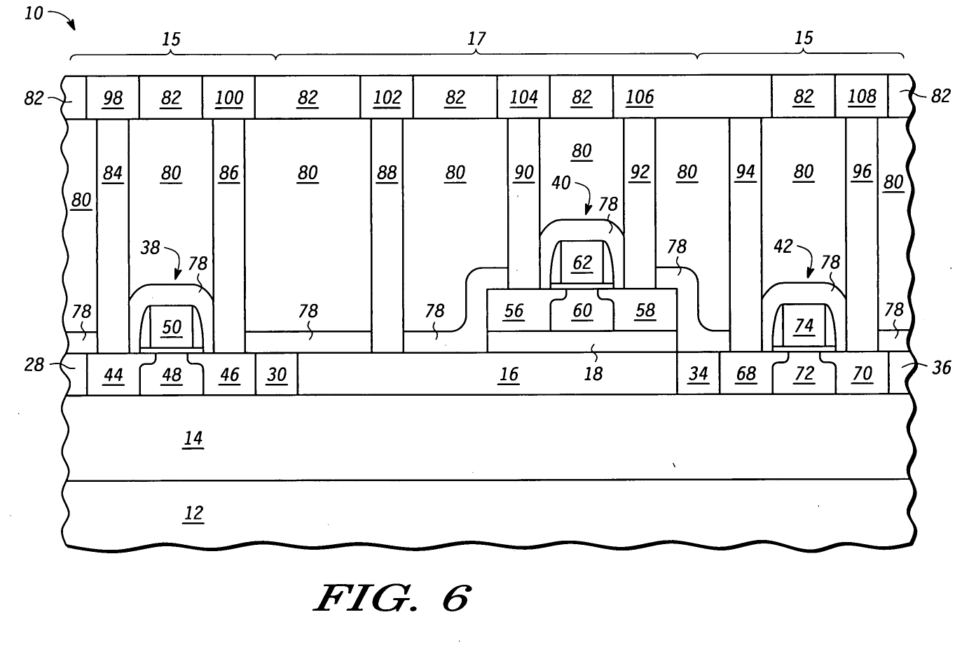

FIG. 6 illustrates a cross-sectional view of semiconductor device 10 of FIG. 5 after formation of contacts. In one embodiment, after formation of transistors 38, 40, and 42, an etch stop layer 78 is blanket deposited over transistors 38, 40, and 42 and over first and second semiconductor layers 16 and 20. An interlevel dielectric (ILD) layer 80 is formed over etch stop layer 78. Openings are then formed in ILD layer 80 to define the locations of contacts 84, 86, 88, 90, 92, 94, and 96, where etch stop layer 78 is used to allow for the formation of openings of varying depths (deeper within region 15 than region 17). In one embodiment, etch stop layer 78 is a nitride layer. Afterwards, a breakthrough etch may be performed to etch through etch stop layer 78 and expose the underlying layer (such as, for example, the source/drain regions of the transistors, or a portion of first semiconductor layer 16 in region 17). Note that conventional processing and materials may be used to form etch stop layer 78, ILD 80, and the contact openings. After formation of the contact openings, they are filled with a conductive material (such as, for example, polysilicon or a metal) and planarized to form contacts (or vias) 84, 86, 88, 90, 92, 94, and 96 which provide contacts to source/drain region 44 of transistor 38, source/drain region 46 of transistors 38, first semiconductor layer 16 within region 17, source/drain region 56 of transistor 40, source/drain region 58 of transistor 40, source/drain region 68 of transistor 42, and source/drain region 70 of transistor 42, respectively.

After formation of the contacts, an intralevel dielectric layer 82 is formed over ILD layer 80. Trench openings are then defined within intralevel dielectric layer 82 which define routings of contacts within intralevel dielectric layer 82. Afterwards, the trench openings are filled and planarized to form an interconnect layer having metal portions 98, 100, 102, 104, 106, and 108. Note that metal portion 98 provides an electrical connection to contact 84, metal portion 100 provides an electrical connection to contact 86, metal portion 102 provides an electrical connection to contact 88, metal portion 104 provides an electrical connection to contact 90, metal portion 106 provides an electrical connection to contacts 92 and 94 (thus electrically connecting source/drain region 58 of transistor 40 with source/drain region 68 of transistor 42), and metal portion 108 provides an electrical connection to contact 96. Conventional materials and processing may be used to form layer 82 and metal 98, 100, 102, 104, 106, and 108.

Note that, as illustrated in FIG. 6, first semiconductor layer 16 may be used to form transistors having different conduction characteristics from those transistors formed using second semiconductor layer 20. Portions of first semiconductor layer 16 may also be used to provide other functions. In the illustrated embodiment, first semiconductor layer 16 within region 17 is used to provide a backgate for transistor 40. In this manner, a voltage may be applied to first semiconductor layer 16 underlying transistor 40 via metal 102 and contact 88 which may be used to affect the threshold voltage of transistor 42. In an alternate embodiment, a portion or portions (not shown) of first semiconductor layer 16 may be used to form a decoupling capacitor in conjunction with substrate 12. Alternatively, a portion or portions (not shown) of first semiconductor layer 16 may be used to form precision resistors, as needed.

Therefore, first and second semiconductor layers 16 and 20 may be used to define different regions in which different types of devices can be independently optimized. In this manner, “holes” and “islands” may be defined across a wafer where, for example, the “holes” may correspond to the regions in which first semiconductor layer 16 is used to form devices and the “islands” may correspond to the regions in which second semiconductor layer 20 is used to form devices. In this manner, different optimizations may be used, while still allowing all devices to maintain the benefits of SOI insulation, since each of the “holes” and the “islands” still correspond to SOI regions.

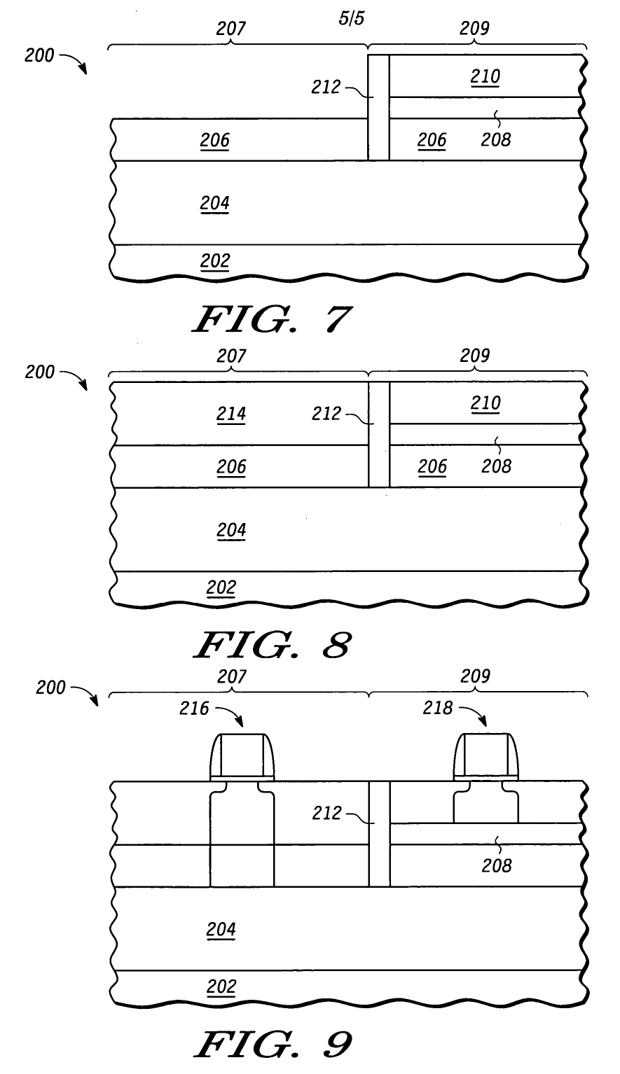

FIGS. 7-9 illustrate cross-sectional views of a semiconductor device 200 in accordance with an alternate embodiment of the present invention. FIG. 7 illustrates a cross-sectional view of semiconductor device 200 having a substrate 202, a buried insulating layer 204 overlying substrate 202, a first semiconductor layer 206 overlying buried insulating layer 204, a bonding layer 208 overlying first semiconductor layer 206, and a second semiconductor layer 210 overlying bonding layer 208. In the illustrated embodiment of FIG. 7 a portion of second semiconductor layer 210 and bonding layer 208 have been removed, exposing a portion of underlying first semiconductor layer 206 in a region 207 and leaving a portion of second semiconductor layer 210 and bonding layer 208 in a region 209. Therefore, in one embodiment, processing for the embodiment of FIG. 7 may be performed in the same or similar manner as described above in reference to FIGS. 1-4. Therefore, the descriptions and examples provided above for substrate 12, buried insulating layer 14, first semiconductor layer 16, bonding layer 18, second semiconductor layer 20, and STIs 28, 30, 34, and 36 also apply to substrate 202, buried insulating layer 204, first semiconductor layer 206, bonding layer 208, second semiconductor layer 210, and STI 212, respectively. Also, note that conventional patterning and etching may be used to remove portions of second semiconductor layer 210 and bonding layer 208 to expose the portion of first semiconductor layer 206 in region 207.

FIG. 8 illustrates a cross-sectional view of semiconductor device 200 of FIG. 7 after formation of a third semiconductor layer 214 (or a semiconductor region 214) over first semiconductor layer 206. In one embodiment, third semiconductor layer 214 is epitaxially grown selectively on first semiconductor layer 206. In one embodiment, since third semiconductor layer 214 is epitaxially grown on first semiconductor layer 206, it may mirror the characteristics of underlying first semiconductor layer 206, depending on the material used for forming third semiconductor layer 214. Therefore, in one embodiment, third semiconductor layer 214 may be considered an extension of first semiconductor layer 206. The material of epitaxially grown third semiconductor layer 214 depends on first semiconductor layer 206. That is, any compatible material (such as, for example, silicon, silicon germanium, or germanium) may be grown on first semiconductor layer 206. Note that the ability to choose different materials for layers 206 and 214 may allow for further tailoring of the strain and conduction properties of layer 214.

Note that in region 207, an SOI region is formed having a thicker active semiconductor layer (corresponding to the combined thicknesses of layers 206 and 214) as compared to the active semiconductor layer (corresponding to layer 210) of the SOI region in region 209. In this manner, the conduction characteristics of subsequently formed transistors may also be based on thickness of the active semiconductor layer, in addition to the material composition, crystal plane, orientation with respect to the MOSFET channel, and strain. Note also that third semiconductor layer 214 may be grown such that it is substantially coplanar with second semiconductor layer 210. In one embodiment, an additional planarization may be performed to achieve the substantial coplanarity after formation of third semiconductor layer 214. Also, as described above in reference to regions 15 and 17, different types of devices may be formed in each of regions 207 and 209 where transistors of different types may be optimized independently, while still maintaining the benefits of SOI isolation.

FIG. 9 illustrates a cross-sectional view of semiconductor device 200 of FIG. 8 after formation of transistors 216 and 218. Transistor 216 is formed using third semiconductor layer 214 (and first semiconductor layer 206, when epitaxially grown) in region 207 and transistor 209 is formed using second semiconductor layer 210 in region 209. Therefore, in one embodiment, transistor 216 is an NMOS transistor and transistor 218 is a PMOS transistor, or vice versa, depending on the materials of layers 206, 214, and 210. In one embodiment, each region may include primarily one type of device; however, each of these regions may also include one or more transistors of a different type, as needed, even though performance of these transistors of a different type may be compromised. Note that conventional materials and processing may be used to form transistors 216 and 218.

Therefore, it can be appreciated how the use of different semiconductor layers may be used to separately optimize N and P channel transistor carrier mobility. Furthermore, the carrier mobility may be optimized while still maintaining the benefits of SOI technology. In one embodiment, holes may be formed within one semiconductor layer to expose portions of an underlying semiconductor layer. In one embodiment, primarily one type of device is formed using (e.g. in and on) the exposed semiconductor layer within the holes while primarily another type of devices is formed using (e.g. in and on) the remaining portions of the overlying semiconductor layer. In one embodiment, semiconductor regions are grown within the holes prior to formation of devices such that the semiconductor regions within the holes are substantially coplanar with the remaining portions of the overlying semiconductor layer. Therefore, one semiconductor layer can be used to achieve improved carrier mobility of one type of device while another semiconductor layer can be used to achieve improved carrier mobility of another type of device. Although the above embodiments have been described in reference to two different semiconductor layers, in alternate embodiments, any number of semiconductor layers may be used, where each may result in different conduction characteristics and where any of these semiconductor layers may correspond to an active semiconductor layer of an SOI region.

One embodiment of the present invention relates to a semiconductor device structure having a first semiconductor layer and a second semiconductor layer in which one is over the other. The first semiconductor layer has a crystal plane, material composition, and a strain, and the second semiconductor layer has a crystal plane, material composition, and a strain. The semiconductor device structure includes first transistors of the first conductivity type in and on the first semiconductor layer having an orientation with respect to the crystal structure of the first semiconductor layer, and second transistors of the second conductivity type in and on the second semiconductor layer having an orientation with respect to the crystal structure of the first semiconductor layer. The first and second transistors have a conduction characteristic defined by a combination of material composition, crystal plane, orientation, and strain. The conduction characteristic of the first transistors is different than that of the conduction characteristic of the second transistors. The conduction characteristic of the first transistors is better for carrier mobility of transistors of the first conductivity type than is the conduction characteristic of the second conductivity type, and the conduction characteristic of the second transistors is better for carrier mobility of the transistors of the second conductivity type than is the conduction characteristic of the first transistors.

Another embodiment relates to a semiconductor device structure having a first semiconductor layer and a second semiconductor layer in which one is over the other, first transistors of the first conductivity type in and on the first semiconductor layer having a conduction characteristic, and second transistors of the second conductivity type in and on the second semiconductor layer having a second conduction characteristic. The conduction characteristic of the first transistors is more favorable for mobility of carriers of transistors of the first conductivity type than for transistors of the second conductivity type.

In yet another embodiment, a method includes providing a first semiconductor layer, forming a second semiconductor layer over the first semiconductor layer, forming first transistors of the first conductivity type in and on the first semiconductor layer having a conduction characteristic, and forming second transistors of the second conductivity type in and on the second semiconductor layer having a second conduction characteristic. The conduction characteristic of the first transistors is more favorable for mobility of carriers of transistors of the first conductivity type than for transistors of the second conductivity type

In another embodiment, a method includes providing a first insulating layer, forming a first semiconductor layer over the first insulating layer, forming a second insulating layer over the first semiconductor layer, forming a second semiconductor layer over the second insulating layer, selectively etching through the second semiconductor layer to form holes in the second semiconductor layer, epitaxially growing semiconductor regions in the holes in the second semiconductor layer, forming first transistors of the first conductivity type in and on the semiconductor regions, and forming second transistors of the second conductivity type in and on the second semiconductor layer.

Although the invention has been described with respect to specific conductivity types or polarity of potentials, skilled artisans appreciated that conductivity types and polarities of potentials may be reversed.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms “a” or “an”, as used herein, are defined as one or more than one.

1. A semiconductor device structure, comprising:
a first semiconductor layer and a second semiconductor layer in which one is over the other, wherein the first semiconductor layer has a crystal plane, material composition, and a strain and the second semiconductor layer has a crystal plane, material composition, and a strain;
first transistors of the first conductivity type in and on the first semiconductor layer having an orientation with respect to the crystal structure of the first semiconductor layer; and
second transistors of the second conductivity type in and on the second semiconductor layer having an orientation with respect to the crystal structure of the first semiconductor layer;
wherein:
the first and second transistors have a conduction characteristic defined by a combination of material composition, crystal plane, orientation, and strain;
the conduction characteristic of the first transistors is different than that of the conduction characteristic of the second transistors;
the conduction characteristic of the first transistors is better for carrier mobility of transistors of the first conductivity type than is the conduction characteristic of the second conductivity type; and
the conduction characteristic of the second transistors is better for carrier mobility of the transistors of the second conductivity type than is the conduction characteristic of the first transistors.

2. The semiconductor device structure of claim 1, further comprising a first insulating layer, wherein the first and second semiconductor layers are over the insulating layer.

3. The semiconductor device structure of claim 2, further comprising providing a second insulating layer between the first semiconductor layer and the second semiconductor layer.

4. The semiconductor device structure of claim 1, wherein:
the first conductivity type is N channel;
the second conductivity type is P channel;
the material composition of the first semiconductor layer comprises silicon; and
the material composition of the second semiconductor layer comprises one of silicon or silicon germanium.

5. The semiconductor device structure of claim 4, wherein the crystal plane of the first semiconductor layer is (100).

6. The semiconductor device structure of claim 5, wherein the crystal plane of the second semiconductor layer is selected from the group consisting of (100), (111), and (110).

7. The semiconductor device structure of claim 5, wherein:
the crystal plane of the second semiconductor layer is (100); and
the orientation of the second transistors is <100>.

8. The semiconductor device structure of claim 7, wherein:
the strain of the first transistors is tensile; and
strain of the second transistors is compressive.

9. The semiconductor device structure of claim 1, wherein:
the first conductivity type is N-type;
the second conductivity type is P-type;
the strain of the first transistors is tensile; and
strain of the second transistors is compressive.

10. The semiconductor device structure of claim 9, wherein:
the first conductivity type is N channel;
the second conductivity type is P channel; and
the crystal plane of the second semiconductor layer is selected from the group consisting of (100), (111), and (110).

11. The semiconductor device structure of claim 9, wherein:
the crystal plane of the second semiconductor layer is (100); and
the orientation of the second transistors is <100>.

12. The semiconductor device structure of claim 9, wherein:
the crystal plane of the second semiconductor layer is (110); and
the orientation of the second transistors is <−110>.

13. The semiconductor device structure of claim 1, further comprising:
a first insulating layer, wherein the first and second semiconductor layers are over the insulating layer; and
a second insulating layer between the first semiconductor layer and the second semiconductor layer;
wherein:
the first conductivity type is N-type;
the second conductivity type is P-type;
the strain of the first transistors is tensile;
strain of the second transistors is compressive;
the crystal plane of the second semiconductor layer is (100);
the orientation of the second transistors is <100>;
the material composition of the first semiconductor layer comprises silicon; and
the material composition of the second semiconductor layer comprises one of silicon or silicon germanium.

14. A semiconductor device structure, comprising:
a first semiconductor layer and a second semiconductor layer in which one is over the other;
first transistors of the first conductivity type in and on the first semiconductor layer having a conduction characteristic; and
second transistors of the second conductivity type in and on the second semiconductor layer having a second conduction characteristic;
wherein the conduction characteristic of the first transistors is more favorable for mobility of carriers of transistors of the first conductivity type than for transistors of the second conductivity type.

15. The semiconductor device structure of claim 14, wherein the first transistors are N-type and wherein the conduction characteristic of the first transistors is characterized by:
the strain being tensile;
the plane being (100); and
the material composition of the first semiconductor layer being silicon.

16. The semiconductor device structure of claim 15, wherein the second transistors are P-type and wherein the conduction characteristic of the second transistors is characterized by:
the strain being compressive;
the plane being (100);
the orientation being <100>; and
the material composition of the second semiconductor layer being one of silicon or silicon germanium.

17. The semiconductor device structure of claim 14, wherein the second transistors are P-type and wherein the conduction characteristic of the second transistors is characterized by:
the strain being compressive;
the plane being (111); and
the material composition of the second semiconductor layer being one of silicon or silicon germanium.

18. The semiconductor device structure of claim 14, wherein the second transistors are P-type and wherein the conduction characteristic of the second transistors is characterized by:
the strain being compressive;
the plane being (100);
the orientation being <100>; and
the material composition of the second semiconductor layer being one of silicon or silicon germanium.

19. A method, comprising:
providing a first semiconductor layer;
forming a second semiconductor layer over the first semiconductor layer;
forming first transistors of the first conductivity type in and on the first semiconductor layer having a conduction characteristic; and
forming second transistors of the second conductivity type in and on the second semiconductor layer having a second conduction characteristic;
wherein the conduction characteristic of the first transistors is more favorable for mobility of carriers of transistors of the first conductivity type than for transistors of the second conductivity type.

20. The method of claim 19, further comprising removing portions of the second semiconductor layer to expose portions of the first semiconductor layer.

21. The method of claim 20, wherein the first transistors are formed in the exposed portions of the first semiconductor layer.

22. The method of claim 21 further comprising providing a first insulating layer, wherein the first and second semiconductor layers are over the insulating layer.

23. The semiconductor device structure of claim 22, further comprising forming an interconnect layer over the first and second transistors that interconnects the first and second transistors.

24. The method of claim 23, further comprising forming a via between the interconnect layer and the first semiconductor layer for providing a bias to at least one of the second transistors.

25. The method of claim 24, further comprising forming a third insulating layer after forming the first and second transistors and prior to forming the interconnect layer.

26. The method of claim 25, wherein:
the first conductivity type is N-type;
the second conductivity type is P-type; and
wherein the conduction characteristic of the first transistors is characterized by:
a crystal plane of the first semiconductor layer being (100);
a strain being tensile; and
a material composition of the first semiconductor layer being silicon; and
wherein the conduction characteristic of the second transistors is characterized by:
a strain being compressive;
a crystal plane of the second semiconductor layer being (100);
an orientation of the second transistors being <100>; and
a material composition of the second semiconductor layer being one of silicon or silicon germanium.

27. The method of claim 25, wherein:
the first conductivity type is P-type; and
the second conductivity type is N-type;
wherein the conduction characteristic of the first transistors is characterized by:
a strain being compressive;
a crystal plane of the second semiconductor layer being (100);
an orientation of the second transistors being <100>; and
a material composition of the first semiconductor layer being one of silicon or silicon germanium; and
wherein the conduction characteristic of the second transistors is characterized by:
a crystal plane being (100);
a strain being tensile; and
a material composition of the second semiconductor layer being silicon.

28. A method, comprising:
providing a first insulating layer;
forming a first semiconductor layer over the first insulating layer;
forming a second insulating layer over the first semiconductor layer;
forming a second semiconductor layer over the second insulating layer;
selectively etching through the second semiconductor layer to form holes in the second semiconductor layer;
epitaxially growing semiconductor regions in the holes in the second semiconductor layer;
forming first transistors of the first conductivity type in and on the semiconductor regions; and
forming second transistors of the second conductivity type in and on the second semiconductor layer.

29. The method of claim 28, wherein:
the first transistors and the second transistors are characterized by a conduction characteristic; and
the conduction characteristic of the first transistors is more favorable for mobility of carriers of transistors of the first conductivity type than for transistors of the second conductivity type.

30. The method of claim 29, wherein:
the first conductivity type is N-type;
the second conductivity type is P-type; and
wherein the conduction characteristic of the first transistors is characterized by:
a crystal plane of the semiconductor regions being (100);
a strain being tensile; and
a material composition of the semiconductor regions being silicon; and
wherein the conduction characteristic of the second transistors is characterized by:
a strain being compressive;
a crystal plane of the second semiconductor layer being (100);
an orientation of the second transistors being <100>; and
a material composition of the second semiconductor layer being one of silicon or silicon germanium.

31. The method of claim 29, wherein:
the first conductivity type is P-type; and
the second conductivity type is N-type;
wherein the conduction characteristic of the first transistors is characterized by:
a strain being compressive;
a crystal plane of the semiconductor regions being (100);
an orientation of the second transistors being <100>; and
a material composition of the semiconductor regions being one of silicon or silicon germanium; and
wherein the conduction characteristic of the second transistors is characterized by:
a crystal plane being (100);
a strain being tensile; and
a material composition of the second semiconductor layer being silicon.
